(19) United States
(12) Patent Application Publication
(10) Pub. No.: US 2026/0002976 A1
(43) Pub. Date: Jan. 1, 2026

(54) FAULT DETECTION CIRCUITRY

(71) Applicant: Cirrus Logic International Semiconductor Ltd., Edinburgh (GB)

(72) Inventor: Sunil SAUNDERS, Oxford (GB)

(73) Assignee: Cirrus Logic International Semiconductor Ltd., Edinburgh (GB)

(21) Appl. No.: 19/042,339

(22) Filed: Jan. 31, 2025

Related U.S. Application Data
(60) Provisional application No. 63/664,774, filed on Jun. 27, 2024.

(51) Int. Cl. G01R 31/28; G01R 31/36; G01R 31/367; H01M 10/42; H01M 10/48

(52) U.S. Cl. CPC G01R 31/2829; G01R 31/3648; G01R 31/367; H01M 10/425; H01M 10/488; H01M 2010/4278; H01M 2220/30

(57) ABSTRACT

Circuitry for processing an analyte signal obtained from an electrochemical cell comprising a first electrode and a second electrode, the circuitry comprising: a first converter, comprising a first input coupled to the first electrode and a first output, the first converter configured to: establish a fixed voltage at the first input; and convert a first current at the first input to a first converted signal at the first output; a second converter, comprising a second input coupled to the second electrode and a second output, the second converter configured to: convert a second current at the second input to a second converter signal at the second output; and processing circuitry configured to detect a fault in the circuitry based on the first and second converter signals.

### TECHNICAL FIELD

The present disclosure relates to detecting faults in circuitry used to measure characteristics in electrochemical cells.

### BACKGROUND

Electrochemical cells are widely used in portable devices, in the form of a battery for providing power to a device, or in the form of a sensor for detecting one or more chemical species, analytes. The health of such electrochemical sensors is key to the operation of many devices into which they are integrated. As such, it may be advantageous to determine a state of such sensors prior to or during their use.

### SUMMARY

According to a first aspect of the disclosure, there is provided Circuitry for processing an analyte signal obtained from an electrochemical cell comprising a first electrode and a second electrode, the circuitry comprising: a first converter, comprising a first input coupled to the first electrode and a first output, the first converter configured to: establish a substantially constant first bias voltage at the first input; and convert a first current at the first input to a first converted signal at the first output; a second converter, comprising a second input coupled to the second electrode and a second output, the second converter configured to: convert a second current at the second input to a second converter signal at the second output; and processing circuitry configured to detect a fault in the circuitry based on the first and second converter signals.

The first converter may comprise a transimpedance amplifier or a current conveyor.

The first converter may be configured to mirror a voltage at a second input of the first converter at the first input of the first converter to establish the first bias voltage at the first input.

The second converter may comprise a transimpedance amplifier or a current conveyor.

The processing circuitry may comprise: one or more analog-to-digital converters, ADCs, configured to convert the first converted signal to a first digital signal, and to convert the second converted signal to a second digital signal, the processing circuitry configured to detect the fault based on the first and second digital signals.

The processing circuitry may comprise: summing circuitry configured to sum the first and second digital signals to obtain a summed output signal; and comparison circuitry configured to: compare the summed output signal to a threshold output value; and detect the fault in the circuitry based on the comparison.

The comparison circuitry may comprise a hysteretic comparator.

The processing circuitry may further comprise: a low-pass filter coupled between the summing circuitry and the comparison circuitry.

The processing circuitry may be configured to transmit a fault interrupt to a host device on detection of the fault.

The processing circuitry may be configured to transition the circuitry into an error state on detection of the fault.

The processing circuitry may be configured to power down the circuitry on detection of the fault.

The processing circuitry may be configured to determine a characteristic of the electrochemical cell based on one or both of the first and second outputs.

The processing circuitry may be configured to: determine a mean of the first and second outputs; and determine the characteristic of the electrochemical cell based on the mean.

The characteristic may comprise one or more of: an impedance; an analyte concentration; a state of health of the electrochemical cell.

The electrochemical cell may comprise a third electrode, the circuitry further comprising: a third converter, comprising a third input coupled to the third electrode and a third output, the third converter configured to: convert a third current at the third input to a third converter signal at the third output.

The processing circuitry may be configured to: determine a characteristic of the electrochemical cell based on the third converter signal.

The first electrode may be a counter electrode, and wherein the second and third electrodes may be working electrodes.

The second and third electrodes may be configured to detect different analytes in the electrochemical cell.

The electrochemical cell may comprise a potentiostatic cell.

The electrochemical cell may comprise a battery cell.

According to another aspect of the disclosure, there is provided circuitry for processing an analyte signal obtained from an electrochemical cell comprising a first electrode, a second electrode, and a third electrode, the circuitry comprising: a first converter, comprising a first input coupled to the first electrode; a second input coupled to the second electrode; and a first output, the first converter configured to: establish a substantially constant first bias voltage at the second input; and convert a first current at the first input to a first converted signal at the first output; a second converter, comprising a third input coupled to the third electrode and a second output, the second converter configured to: convert a second current at the third input to a second converter signal at the second output; and processing circuitry configured to detect a fault in the circuitry based on the first and second converter signals.

The first electrode may comprise a counter electrode, the second electrode comprises a reference electrode, and the third electrode comprises a working electrode.

The second converter may be configured to establish a substantially constant second bias voltage at the third electrode.

According to another aspect of the disclosure, there is provided an integrated circuit (IC), comprising the circuitry described above.

According to another aspect of the disclosure, there is provided wearable device, comprising the circuitry described above; and the first and second electrodes.

The wearable device may comprise one of an analyte monitor, a glucose monitor, a battery monitor, a mobile computing device, a smart watch, a remote control device, a home automation controller, an audio player, a video player, a mobile telephone, and a smartphone.

The electrochemical cell may comprise an electrochemical sensor (e.g. potentiostatic or potentiometric sensor), or may comprise a battery cell (i.e. a power source). Whilst examples described herein refer to “an electrochemical cell”, it will be appreciated that described solutions are applicable to the characterisation of multiple electrochemical cells, such as a plurality of battery cells making up a battery.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIG. 1 illustrates a schematic diagram and electrical equivalent circuit for a three-electrode electrochemical cell;

FIG. 2 illustrates a schematic diagram and electrical equivalent circuit for a two-electrode electrochemical cell;

FIG. 3A is a schematic diagram of an example prior art measurement circuit;

FIG. 3B is a schematic diagram of the circuit of FIG. 3A, showing the measurement circuitry in more detail;

FIG. 4 is a schematic diagram of an example measurement circuit;

FIG. 5 is a schematic diagram of the measurement circuit of FIG. 4 with a fault;

FIG. 6 is a schematic diagram of processing circuitry for processing a signal derived from the measurement circuit of FIG. 4;

FIG. 7 is a schematic diagram of an example measurement circuit;

FIG. 8 is a schematic diagram of an example measurement circuit;

FIG. 9 is a schematic diagram of an example measurement circuit;

FIG. 10 is a schematic diagram of an example measurement circuit; and

FIG. 11 is a block diagram of an electronic device according to embodiments of the present disclosure.

### DESCRIPTION OF EMBODIMENTS

Electrochemical sensors are widely used for the detection of one or more particular chemical species, analytes, as an oxidation or reduction current. Such sensors comprise an electrochemical cell, consisting of two or more electrodes configured for contact with an analyte whose concentration is to be ascertained. Such sensors also comprise circuitry for driving one or more of the electrodes and for measuring a response at one or more of the electrodes. Batteries also comprise one or more electrochemical cells which typically consist of two or more electrodes (e.g., an anode and a cathode) configured for contact with a conductive electrolyte. Characteristics of batteries may be ascertained using drive and measurement circuitry similar to that used for characterising electrochemical cells in electrochemical sensors.

Embodiments of the present disclosure provide various novel signal processing techniques for the determination of characteristics associated with electrochemical cells and systems (such as sensors, batteries and the like) into which electrochemical cells are incorporated.

Various implementation details pertaining to drive and measurement circuitry for obtaining characterising impedance measurements of an electrochemical cell are described below. Such embodiments focus primarily on electrochemical cells comprised in sensors (e.g. potentiostats). For example, the embodiments described herein may be implemented as part of an analyte monitoring system, such as a continuous glucose monitor (CGM). It will be appreciated, however, that embodiments are not limited to use with electrochemical sensors. For example, batteries also comprise one or more electrochemical cells which typically consist of two or more electrodes (e.g., an anode and a cathode) configured for contact with a conductive electrolyte. Impedance characteristics of batteries (e.g. comprising lithium ion or silver oxide cell(s)) may be ascertained using drive and measurement circuitry described herein. For example, embodiments of the present disclose may be implemented as part of battery monitoring device (e.g. to monitor the status and/or health of a battery).

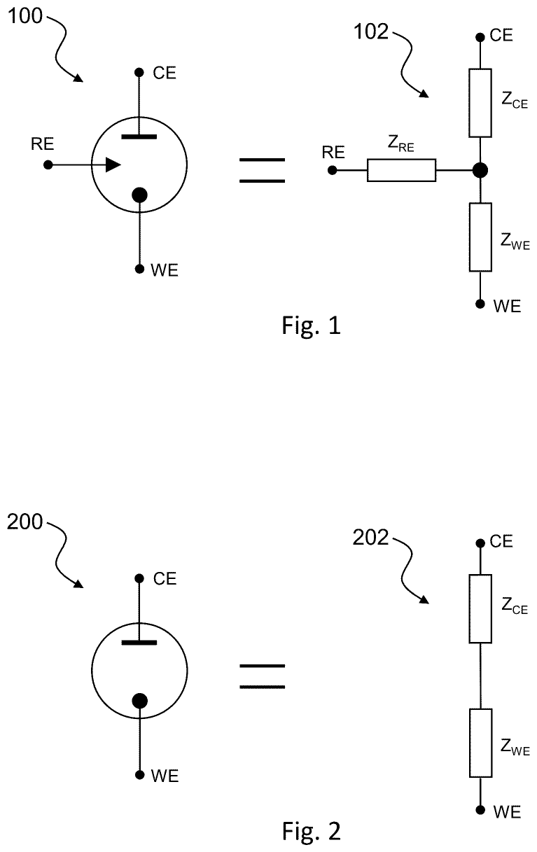

FIG. 1 is a schematic diagram of an example electrochemical cell 100 comprising three electrodes, namely a counter electrode CE, a working electrode WE and a reference electrode RE. FIG. 1 also shows an equivalent circuit 102 for the electrochemical cell 100 comprising a counter electrode impedance ZCE, a working electrode impedance ZWE and a reference electrode impedance ZRE.

FIG. 2 is a schematic diagram of another example electrochemical cell 200 comprising two electrodes, namely a counter electrode CE and a working electrode WE. The electrochemical cell 200 varies for the cell 100 with the omission of the reference electrode RE. FIG. 2 also shows an equivalent circuit 102 for the electrochemical cell 200 comprising a counter electrode impedance ZCE and a working electrode impedance ZWE.

In some embodiments, the working electrode WE comprises an assay or chemical of interest. For example for the analysis of glucose as an analyte, the working electrode may comprise a layer of glucose oxidase. The counter electrode CE is provided to form an electrical or ohmic connection with the working electrode WE. Optionally, the reference electrode is provided, which is typically a sensing point between the working electrode WE and the counter electrode CE, allowing independent measurement of the potential associated with each of the working and counter electrodes WE. CE, rather than just measuring a potential difference between the counter and working electrodes CE, WE.

Embodiments of the disclosure will be described with reference to these example electrochemical cells 100, 200. It will be appreciated, however, that the techniques and apparatus described herein may be used in conjunction with any conceivable electrochemical system, including but not limited to electrochemical cells comprising at least two electrodes (e.g. a counter electrode CE, a working electrode WE and optionally a reference electrode RE), or electrochemical cells with more than three electrodes (e.g. two or more counter electrodes and/or two or more working electrodes). Electrodes of the electrochemical cells described herein may also be referred to as anodes and/or cathodes as is conventional in the field of electrical batteries.

To determine a characteristic of either of the electrochemical cells 100, 200, and therefore an analyte concentration, it is conventional to apply a bias voltage VCE at the counter electrode CE and measure a current at the working electrode WE. When provided, the reference electrode RE may be used to measure a voltage drop between the working electrode WE and the reference electrode RE. The bias voltage is then adjusted to maintain the voltage drop between the reference and working electrodes RE, WE constant. As the resistance in the cell 100 increases, the current measured at the working electrode WE decreases. Likewise, as the resistance in the cell 100 decreases, the current measured at the working electrode WE increases. Thus, the electrochemical cell 100 reaches a state of equilibrium where the voltage drop between the reference electrode RE and the working electrode WE is maintained constant. Since the bias voltage at the counter electrode CE and the measured current at WE are known, the resistance of the cell 100 can be ascertained.

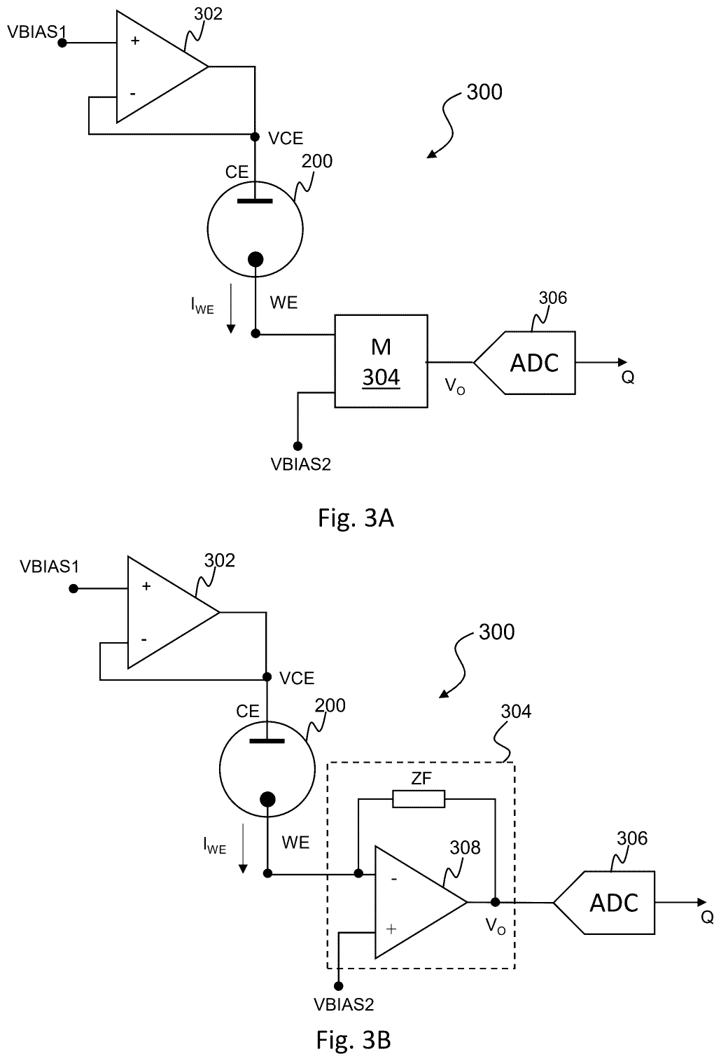

FIG. 3A illustrates an example prior art drive and measurement circuit 300 which is configured to implement the above explained cell characterisation, specifically for measuring an analyte concentration in the electrochemical cell 200 shown in FIG. 2. The circuit 300 comprises a first amplifier 302 and a measurement circuit 304. Each of the first amplifier 302 and the measurement circuit 304 may comprise one or more op-amps. A non-inverting input of the first amplifier 302 is coupled to a bias voltage VBIAS which may be generated by a digital-to-analog converter DAC (not shown). An inverting input of the first amplifier 302 is coupled to the counter electrode CE. An output of the first amplifier 302 is coupled to the counter electrode CE and configured to drive the counter electrode CE with a counter electrode bias voltage VCE. The counter electrode bias voltage VCE applied at the counter electrode CE by the first amplifier 302 is proportional to the difference between the bias voltage VBIAS1 and the voltage at the counter electrode CE.

The measurement circuit 304 is coupled between the working electrode WE and an analog-to-digital converter (ADC) 306. The measurement circuit 304 is operable to output to the ADC 306 a signal proportional to the current flowing from the working electrode WE. The ADC 306 then converts the signal output from the measurement circuit 304 to a digital output signal Q which represents the current flowing from the working electrode WE.

The measurement circuit 304 is typically implemented as a transimpedance amplifier (TIA) or a current conveyor (CC).

FIG. 3B illustrates an example implementation of the drive and measurement circuit 300, the measurement circuit 304 implemented as a TIA comprising a second amplifier 308. An inverting input of the second amplifier 308 is coupled to the working electrode WE and a non-inverting input of the second amplifier 308 is coupled to a fixed bias voltage VBIAS2, for example ground GND or a non-zero voltage. A feedback impedance ZF is coupled between the non-inverting input and an output of the second amplifier 308. As such, the second amplifier 308 operates as a TIA. The second amplifier 308 is thus operable to output a voltage VO which is proportional to the current IWE at the working electrode WE. The output voltage VO is then provided to the analog-to-digital converter (ADC) 306 which outputs a digital output Q which represents the current IWE at the working electrode WE.

To bias the counter electrode CE, and therefore the electrochemical cell 200, at different voltages, the bias voltage VBIAS1 provided to the first amplifier 302 may be adjusted. The bias voltage VBIAS1 may be adjusted between a reference voltage (e.g. ground or zero volts) and the supply voltage VDD. With the non-inverting input of the second amplifier 304 is set at VDD/2, a positive bias may be applied to the cell 200 by maintaining the bias voltage VBIAS1 above VDD/2. Likewise, a negative bias may be applied to the cell 100 by maintaining the bias voltage VBIAS1 below VDD/2.

The drive and measurement circuitry 200 described above may be used to implement electro-impedance spectroscopy (EIS) on the cell 100.

To implement EIS, it is conventional to modulate the bias voltage VBIAS1, for example by applying a sine wave having a modulated frequency and/or amplitude. The measurement circuit 304 and ADC 306 may then be used to measure a response of the cell 200 to that sine wave, in the form of the output voltage VO. The frequency of the sine wave may be adjusted over a range of frequencies in order to obtain a series of frequency dependent impedance measurements of the cell 200. Alternatively, one or more frequencies of interest may be known (identified, estimated, modelled or otherwise predetermined) such that the sine wave which is applied is at that frequency of interest. Each frequency of interest may be chosen to minimize variation in measurements or maximise a response of the cell for determining a particular characteristic.

An alternative known approach to the above EIS technique is chronoamperometry (CA) in which a step or impulse function stimulus is applied to the cell 200. A transfer function between the stimulus and a response of the cell 200 to that stimulus can then be estimated or inferred.

In some embodiments, the cells 100, 200 may be potentiometric as opposed to potentiostatic. In such cases, the working electrode WE may comprise an ion-selective membrane 104, which may be configured to uptake only a specific ion (in this case the cation, 1+) from an electrolyte solution 106. As such, the potential difference between the working electrode WE and the reference electrode RE will depend on the concentration of that particular ion analyte in the electrolyte solution 106. Thus, the potential difference across the cells 100, 200 may be measured to ascertain ion analyte concentration. A typical approach to such measurement is to couple each of the working and reference electrodes WE, RE to high input impedance buffers which are used, in turn, to drive one or more ADCs (e.g. two single ended ADCs or one differential ADC). A digital output signal is then derived which represents the potential difference between working and reference electrode WE, RE of the cell 100.

In the above examples described with reference to FIGS. 3A and 3B, drive circuitry is provided to apply a stimulus to the cell 200. Where the cell 200 is implemented as a power source or a potentiometric sensor, it may not be necessary to apply a stimulus to induce a response from the cell 200.

As noted above, the circuit 300 shown in FIG. 3 may be implemented as part of an analyte monitoring system, such as a continuous glucose monitor (CGM). It will be appreciated that any error in reported glucose concentration can result in serious harm to a subject being monitored. In such applications, it is therefore critical that a fault in the circuit 300 is known before erroneous values are reported. Traditional methods for fault detection include voltage measurement circuits to ensure the voltage across the working electrode WE and counter electrode CE is as intended. However, these methods may not detect all fault conditions, for example a weak resistive fault may cause a leakage current that leads to an inaccurate analyte measurement whilst not causing sufficient load on the amplifier to affect the voltage across the sensor.

Embodiments of the present disclosure aim to address or at least ameliorate one or more of the above issues by providing a novel architecture for both characterisation of an electrochemical cell and fault detection of systems comprising the same electrochemical cell. As noted above, the measurement circuit 304 is implemented as a current conveyor or a TIA. A characteristic of both such devices is their ability to buffer an input current Iwe whilst maintaining a voltage at their first input equal to a voltage applied to their second input. In the case of a current conveyor such a first input is conventionally denoted X, and such a second input is conventionally denoted Y. In the case of a TIA, such a first input is conventionally a non-inverting input of the second amplifier 308 and such a second input is conventionally an inverting input of the second amplifier 308 (see FIG. 3B). The inventors have realised that the nature of such converters (TIA or CC) can be utilised both to maintain a voltage at each of the counter and working electrodes CE, WE at a known value, and for measurement of current flowing at the counter and working electrodes CE. Using Kirchoff's law, the sum of currents flowing at the counter and working electrodes CE, WE can be used to determine a fault in the representative circuit.

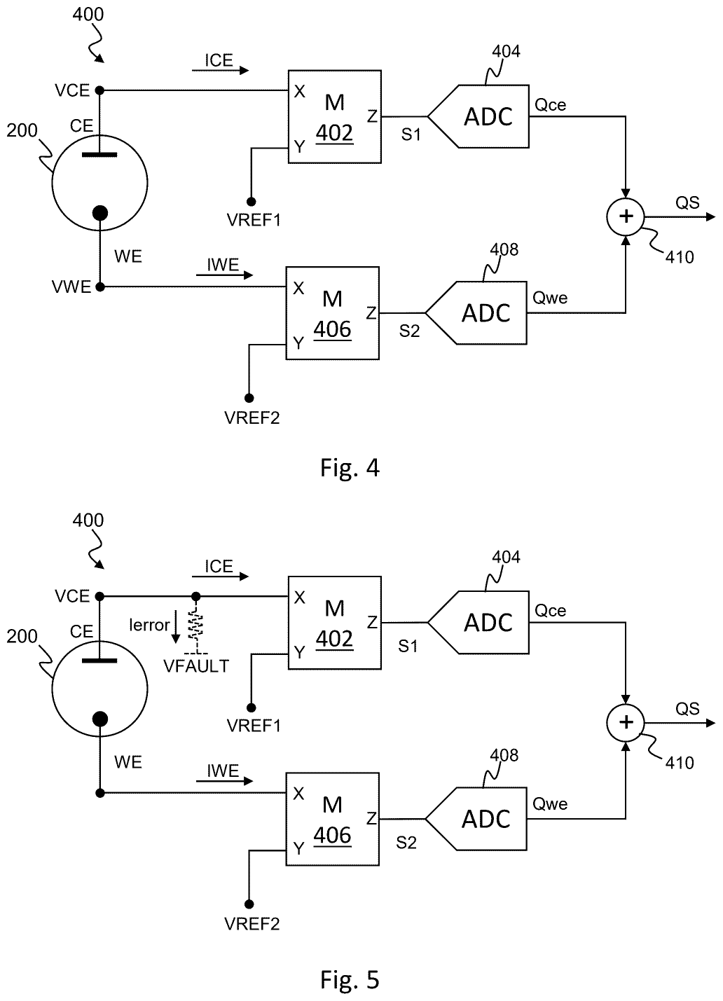

FIG. 4 is a schematic diagram of a measurement circuit 400 according to embodiments of the present disclosure. The measurement circuit comprises a first converter 402, a first ADC 404, a second converter 406, a second ADC 408, and summing circuitry 410.

The first input X of the first converter 402 is coupled to the counter electrode CE. The second input Y of the first converter 402 is coupled to a first reference voltage VREF1. The output Z of the first converter 402 is coupled to an input of the first ADC 404. The first ADC 404 is configured to convert a signal S1 at the output Z of the first converter 402 to a digital output Qce representing the current ICE at the counter electrode CE.

The first input X of the second converter 406 is coupled to the working electrode WE. The second input Y of the second converter 406 is coupled to a second reference voltage VREF2. The output Z of the second converter 406 is couple to an input of the second ADC 408. The second ADC 408 is configured to convert a signal S2 at the output Z of the second converter 406 to a digital output Qwe representing the current IWE at the working electrode WE.

The outputs of the first and second ADCs 404, 408 are provided as inputs to the summing circuitry 410 which is configured to sum the outputs to generate a summed output signal QS. As will be described in more detail below, the output signal QS may be used to detect a fault associated with the measurement circuit 400.

The first and second converters 402, 406 each comprises a first input X, a second input Y, and an output Z. A characteristic of each of the first and second converters 402, 406 is its ability to establish on its first input X a voltage equal to the voltage provided to its second input Y. In the example shown in FIG. 4, the converters 402, 406 each comprise a current conveyor (CC) configured to buffer a respective input current ICE, IWE whilst maintaining a voltage at their first input X equal to a voltage applied to the second input Y. Another example of a circuit element which exhibits such a characteristic is a transimpedance amplifier (TIA).

As such, the first converter 402 is configured to mirror the first reference voltage VREF1 onto the counter electrode CE, thereby maintaining a fixed voltage VCE at the counter electrode CE of the cell 200 equal to the first reference voltage VREF1. In addition, the first converter 402 can be used to measure a current ICE at the counter electrode CE, as reflected at the output Z of the first converter 402 and the output Qce of the ADC 306. In this configuration, the first converter 402 therefore provides multiple functions, removing the need for separate circuitry to measure the voltage across the cell 200. This has the effect of improving the efficiency of fault detection, when compared to prior art arrangements.

The second converter 406 operates in a similar manner to the measurement circuit 304 of FIG. 3, converting a current IWE at the working electrode WE to a voltage VCE at the counter electrode CE. The second converter 406 also maintains a voltage VWE at the working electrode WE substantially equal to the second reference voltage VREF2. As such, the voltage across the electrochemical cell 200 is maintained at a known reference voltage drop.

It will be understood that according to Kirchoff's current law, the sum of currents flowing into a node in an electrical circuit should be equal to the sum of currents flowing out of that node. Equivalently, the algebraic sum of currents in a network of conductors meeting at a point is zero. Applying this law to the electrochemical cell 200, the sum of the current ICE at the counter electrode CE and the current IWE at the working electrode WE should be equal to zero, i.e.:

$${I}_{CE} + {I}_{WE} \approx 0$$

Thus, in normal operating conditions, the summed output signal Qs should be approximately equal to zero (taking into account non-ideal effects and potential inaccuracies in conversion by various circuit elements of the circuit 400).

A fault in the circuit 400 will manifest in current leakage which will cause a change in either the counter electrode current ICE or the working electrode current IWE. FIG. 5 schematically illustrates the circuit 400 with an example fault condition. In this example, the fault condition is manifested by an error current Ierror flowing from the counter electrode CE. Using Kirchoff's current law, the sum of the working electrode current IWE and the counter electrode current ICE will be equal to the negative of the error current Ierror, i.e.:

$${I}_{CE} + {I}_{WE} \approx - {I}_{error}$$

From this example, it can be seen that a non-zero result of the summation QS of the outputs Qce, Qwe of the first and second ADCs 404, 408 indicates a fault condition in the circuit 400.

Thus, the summing circuitry 410 is configured to sum the outputs Qce, Qwe which represent the currents ICE, IWE flowing at respective counter and working electrodes CE, WE. This summed output QS can be processed to determine a fault status or condition. If the summed output QS is equal to zero or within a threshold range of zero, it may be determined that no faults are present in the circuit 400. If the summed output QS is non-zero or outside of a threshold range of zero, it may be determined that a fault is present in the circuit 400. The circuit 400 may comprise additional processing circuitry (not shown) for processing the summed output QS.

The threshold range may be programmable. For example, the threshold range may be programmable in dependence on specific application of the measurement circuit 400, or based on manufacturer or customer considerations, such as risk appetite to faults, etc. In another example, the threshold range may be adjusted based on temperature at the cell 200 or circuit 400. It will be appreciated that temperature fluctuations may affect errors associated with elements of the circuit 400 which may lead to fluctuations in converted signals. Such fluctuations may be taken into account by adjustments of the programmed threshold range. In another example, the threshold range may be set based on the expected or received counter and/or working electrode currents ICE, IWE. For example, error in the first and second converters 402, 406 may increase with signal level of signals at their inputs. As signal error associated with the measurement circuit 400 increases, it may be beneficial to increase the threshold range to take into account potential increases in (non-fault) error in the output signal Qs.

In the circuit 400 of FIGS. 4 and 5, separate ADCs 404, 408 are provided to convert respective outputs Z of the first and second converters 402, 406 to the digital output signals Qce, Qwe. In other embodiments, a single multiplexed ADC may be provided. Alternatively, a differential ADC may be implemented which takes the outputs Z of the first and second converters 402, 406 as inputs and outputs a digital signal which represents the difference between those signals. Alternatively, the ADCs 404, 408 may be omitted and the summing circuitry 410 may be implemented in the analog domain. In which case, optionally, an ADC may be provided to convert the summed output of such analog summing circuitry into the digital domain. In any case, circuitry is provided to compare signals derived from the currents ICE, IWE flowing at the counter and working electrodes CE, WE to detect a fault condition associated with the measurement circuit 400.

As noted above, additional processing circuitry may be provided for processing the summed output QS to fault detection.

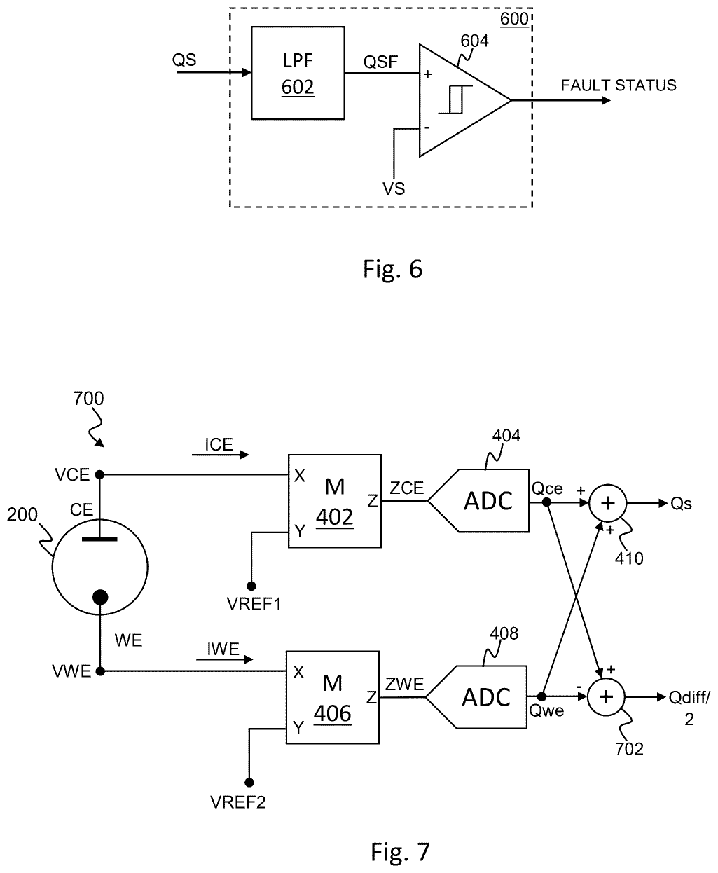

FIG. 6 is a schematic diagram of example processing circuitry 600 for processing the summed output signal QS output from the summing circuitry 410 of the circuit 400 shown in FIG. 4. The processing circuitry 600 may be integrated with the measurement circuit 400 shown in FIG. 4.

The processing circuitry 600 comprises an optional lowpass filter (LPF) 602 and a comparator 604. The LPF 602 is configured to receive the summed output signal QS and lowpass filter that signal to remove noise. The filtered summed output signal GSF is then provided to a first (non-inverting) input of the comparator 604. A second input of the comparator 604 is coupled to a reference signal VS. The comparator 604 is configured to output a binary output (1 or 0) in dependence on whether the filtered summed output signal QSF is great or less than a level of the reference signal VS. The reference signal VS may represent a threshold of the output signal QS over which it a fault may be flagged. As noted above with reference to FIG. 4, the sum of the counter and working electrode currents ICE, IWE being not equal to zero may indicate a fault condition of the circuit 400. In some embodiments, such as that shown in FIG. 6, the comparator 604 may be a hysteretic comparator. Whilst the processing circuitry 600 of FIG. 6 is implemented in the digital domain, such circuitry may equally be implemented in the analog domain, for example where the ADCs 404, 408 are omitted.

It will be appreciated that the circuit 400 shown in FIG. 4 may be used to determine a characteristic of the cell 200 as well as to detect a fault in the circuit 400. Such characteristics may comprise on or more of an impedance of the cell 200, an analyte concentration, a state of health of the cell 200, or any other conceivable condition of the cell 200. A characteristic of the cell 200 may be ascertained from a signal derived from the first converter 402 and/or the second converter 406. For example, the working electrode current IWE may be used to determine a characteristic of the cell 200, as is conventional (see FIGS. 2 and 3). Additionally, or alternatively, the counter electrode current ICE may be used to determine an impedance or other characteristic of the cell 200. Additionally, or alternatively, the combination of counter and working electrode currents ICE, IWE may be used to determine a characteristic of the cell 200. For example, the outputs V1, V2 of the first and second converters 402, 406 may be combined to obtain a measurement of a characteristic of the cell 200. Additionally, or alternatively, one of the outputs V1, V2 may be relied upon for determining a characteristic of the cell 200, whilst the other of the outputs V1, V2 may be used to determine potential corruption of the signal being used to determine the characteristic of the cell 200. For example, the measurement circuit 400 may be provided in a signal chain the includes wired and/or wireless links and converters which may introduce interference to signals derived rom the cell 200. By sending signals derived from both of the first and second converters 402, 406, redundancy is introduced which can increase resilience of downstream processing to such interference.

As noted above, the signal Qs output from the summing circuitry 410 may be processed to determine a fault condition. In response to detecting a fault, such processing circuitry may be configured to raise an interrupt, which may be transmitted to a host device. To do so, the processing circuitry may be configured to raise an interrupt on a pin of the host device, by driving that pin to a different voltage. In addition, or as an alternative to raising an interrupt, the processing circuitry may be configured to cause the circuit 400 to transition into an error state. Such an error state may power down the measurement circuit 400, and/or prevent the circuit 400 from outputting measurements to downstream circuitry. In doing so, active unknown states of the circuit 400 may be avoided, thereby preventing unknown currents flowing through a fluid associated with the electrochemical cell 200, such as interstitial fluid of a subject. In addition or as an alternative to raising an interrupt or entering an error state, a sample which is obtained when a fault is detected could be discarded and the circuit 400 could continue to operate. If subsequent samples are then received and the summed output signal Qs reverts to a normal value (e.g. close to zero), the circuit 400 could continue to operate. If, however, a predetermined number of successive samples (or a predetermined number of samples over a set number of total samples) exhibit a fault condition, the circuit 400 could be placed in an error state and/or an interrupt could be raised.

FIG. 7 schematically illustrates a measurement circuit 700 which is a variation of the circuit 400 of FIG. 4, like parts being denoted by like numbering. The measurement circuit 700 differs from the circuit 400 only by the addition of subtraction circuitry 702 configured to receive first and second digital output signal Qce, Qwe from the first and second ADCs 404, 408 and configured to subtract the second output signal Qce from the first output signal Qwe to obtain a difference signal Qdiff. As noted above, the summed output signal Qs represents the difference between the modulus of the counter and reference currents ICE, IWE. The difference signal Qdiff can be used to determine a mean Qmean representing a mean of the counter and working electrode currents ICE, IWE, i.e.:

$$Qmean = Qdiff / 2$$

The skilled person will appreciate that the mean signal Qmean will have reduced common mode noise when compared to the first and second output signals Qce, Qwe taken alone.

In the embodiments described above, the electrochemical cell 200 of FIG. 2 is shown. Embodiments are not so limited. For example, embodiments may be equally applicable to the cell 100 shown in FIG. 1, which includes a reference electrode RE in addition to counter and working electrodes CE, WE.

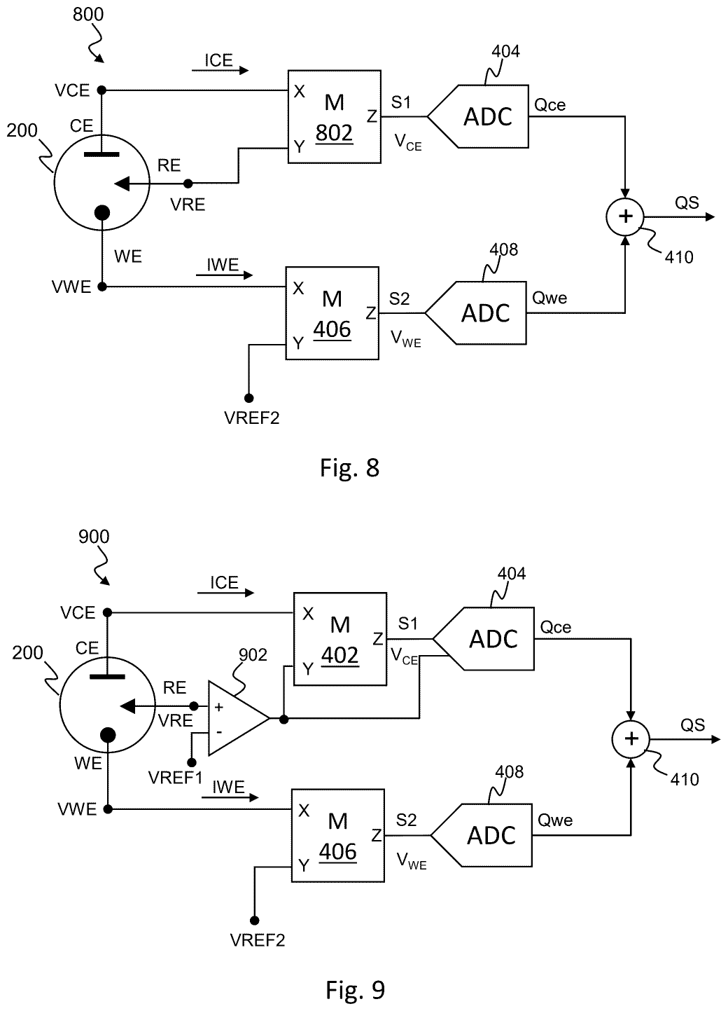

FIG. 8 is a schematic diagram of a measurement circuit 800 which is a variation of the circuit 400 shown in FIG. 4, like parts being denoted like reference numerals. The measurement circuit 800 is configured to determine characteristics of the electrochemical cell 100 comprising a reference electrode RE.

The circuit 800 differs from the circuit 400 of FIG. 4 in that the first converter 402 is replaced with a different first converter 802. The first converter 802 has a first input X coupled to the counter electrode CE, a second input coupled to the reference electrode RE, and an output Z coupled to the input of the ADC 404. Instead of establishing a fixed voltage at the counter electrode CE (as is the case for the first converter 402 of FIG. 4), the first converter 802 of the circuit 800 of FIG. 8 is configured to apply a voltage VCE at the counter electrode to establish a fixed (or predetermined) voltage VRE at the reference electrode RE. In doing so, the first converter 802 is configured to maintain a voltage drop between the reference and working electrodes RE, WE substantially constant.

FIG. 9 is a schematic diagram of a measurement circuit 900 which is a variation of the circuit 400 shown in FIG. 4, like parts being denoted like reference numerals. Like the circuitry 800 described above, the measurement circuit 900 is configured to determine characteristics of the electrochemical cell 100 comprising a reference electrode RE.

The measurement circuit 900 differs from the circuit 400 of FIG. 4 with the addition of a reference comparator 902. The reference comparator 902 has a first (inverting) input coupled to the reference electrode RE of the cell 100, a second (non-inverting) input coupled to the first reference voltage VREF1, and an output coupled to the second input Y of the first converter 402. The reference comparator 902 is configured to maintain the reference electrode voltage VRE at the reference electrode substantially constant or fixed whilst allowing a voltage at the second input Y of the first converter 402 to follow the counter electrode voltage VCE at the counter electrode CE. An output of the reference converter 902 may also be provided to the ADC 404 as a reference voltage for the ADC 404.

Embodiments of the present disclosure are also applicable to cells having more than one working electrode WE or more than one counter electrode CE.

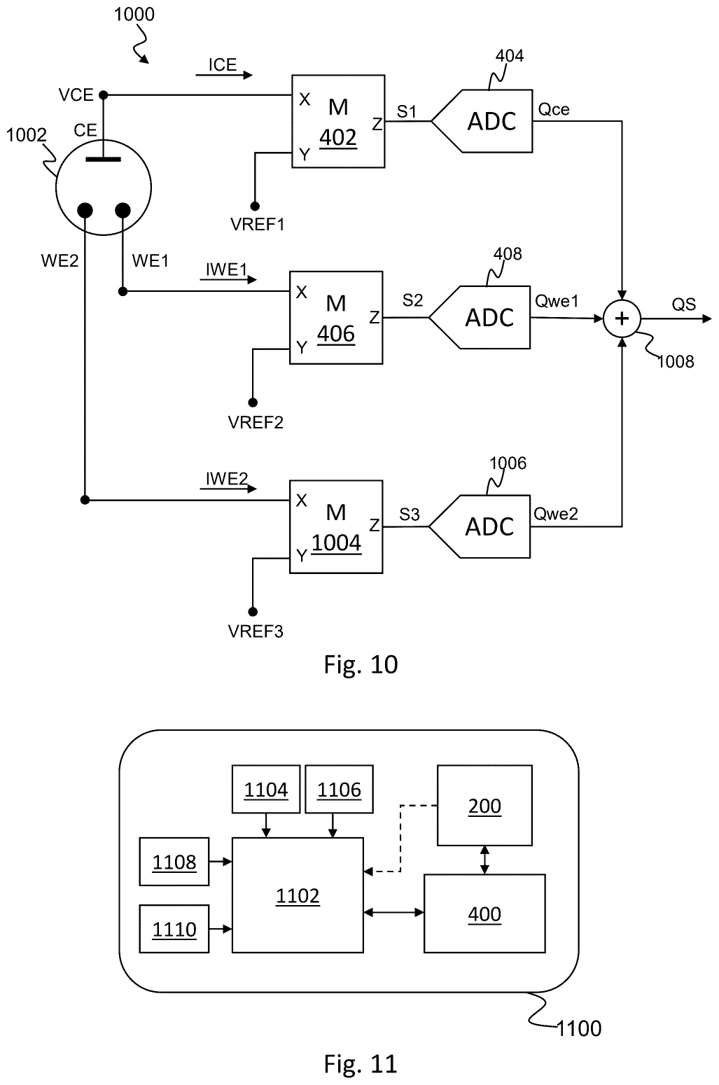

FIG. 10 is a schematic diagram of a measurement circuit 1000 for a characterisation of an electrochemical cell 1002 comprising a counter electrode CE and first and second working electrodes WE1, WE2. The circuit 1000 is an extension of the circuit 400 of FIG. 4, like parts being given like numbering. The measurement circuit 1000 comprises the first converter 402, the first ADC 404, the second converter 406, and the second ADC 408. In addition, the measurement circuit 1000 comprises a third converter 1004, a third ADC 1006, and summing circuitry 1008.

The first input X of the first converter 402 is coupled to the counter electrode CE. The second input Y of the first converter 402 is coupled to a first reference voltage VREF1. The output Z of the first converter 402 is coupled to an input of the first ADC 404. The first ADC 404 is configured to convert a signal S1 at the output Z of the first converter 402 to a digital output Qce representing the current ICE at the counter electrode CE.

The first input X of the second converter 406 is coupled to the first working electrode WE1 of the cell 1002. The second input Y of the second converter 406 is coupled to a second reference voltage VREF2. The output Z of the second converter 406 is couple to an input of the second ADC 408. The second ADC 408 is configured to convert a signal S2 at the output Z of the second converter 406 to a digital output Qwe representing the current IWE1 at the first working electrode WE1.

The third converter 1004 may be similar in form and function to the second converter 406. A first input of the third converter 1004 is coupled to the second working electrode WE2 of the cell 1002. The second input Y of the third converter 1004 is coupled to a third reference voltage VREF3. The output Z of the third converter 1004 is couple to an input of the third ADC 1006. The third ADC 1006 is configured to convert a signal S3 at the output Z of the second converter 406 to a digital output Qwe representing the current IWE2 at the second working electrode WE2.

The outputs Qce, Qwe1, Qwe2 of the first, second, and third ADCs 402, 404, 1006 are provided as inputs to the summing circuitry 1008 which is configured to sum the outputs Qce, Qwe1, Qwe2 to generate a summed output signal QS. The output signal QS may be used to detect a fault associated with the measurement circuit 1000 in a similar manner to that described above with reference to the measurement circuit 400 shown in FIG. 4.

The third converter 1004 operates in a similar manner to second converter 406, converting the second working electrode current IWE2 at the second working electrode WE2 to a signal S3. The third converter 1004 also maintains a voltage VWE2 at the second working electrode WE2 substantially at the third reference voltage VREF3. As such, the voltage between the counter electrode CE and each of the first and second working electrodes WE1, WE2 is maintained at known reference values. The second and third reference voltage VREF2, VREF3 may be equal or set to different voltages depending on the characteristics of respective working electrode WE1, WE2. For example, different biases may be required for different analytes of interest. In such circumstances, the second and third voltages VREF2, VREF3 may be different. In another example, the second working electrode WE2 may be provided merely for redundancy, the first and second working electrodes WE1, WE2 configured to measure the same analyte. In which case, the second and third reference voltages VREF2, VREF3 may be equal in value.

FIG. 5 illustrates an example electronic device 1100 comprising the electrochemical cell 200 according to embodiments of the present disclosure. The example shown in FIG. 5 is provided for explanatory purposes only and may comprise one or more additional components or fewer components depending on the specific application of the electronic device 1100. In the example in FIG. 11, the device 1100 comprises the drive and measurement circuit 400 of FIG. 4. It will be appreciated that the circuit 400 may be replaced with the measurement circuit 700 of FIG. 7 or the measurement circuit 1000 of FIG. 10 without departing from the scope of the present disclosure. Each circuit 400, 700, 1000 may be configured to generate a digital output which is representative of a characteristic of the cell 200, in addition to a digital output which is indicative of a fault associated with the respective circuit 400, 700, 1000.

In the example shown, the electronic device 1100 comprises a processor 1102 which may be configured to control the drive and measurement circuit 400 and process signals received from the drive and measurement circuit 400. The processor 1102 may be an applications processor AP, a digital signal processor (DSP). The processor may be formed of a single processor or multiple processors. For example, the electronic device 1100 may comprise an AP and a DSP.

The device 1100 may further comprise a memory 1104, which may in practice be provided as a single component or as multiple components. The memory 1104 may be provided for storing data and/or program instructions. The memory 1104 may comprise non-volatile memory. The memory 1104 may additionally or alternatively comprise volatile memory.

The device 1100 may further comprise a transceiver 1106, which may be provided to communicate (wired or wirelessly) with external devices, such as a host device (e.g. mobile device or smartphone) or a remote device (e.g. via the internet).

The device 1100 may further comprise a temperature sensor 1108 and may comprise other sensors (not shown).

The device 1100 may further comprise a real time clock (RTC) 1110 which may be used to timestamp data obtained from the cell 200 or data derived from data obtained from the cell 200, which may be stored in the memory 1104.

The device 1100 may further comprise an external or internal power source (such as a battery). It will be appreciated that where the cell 200 is a battery, the cell 200 may provide power to the device 1100 as denoted by the dotted line between the cell 200 and the processor 1102.

Non-limited examples of the electronic device 1100 include an analyte monitoring device or an analyte sensing device, a continuous glucose monitor, a battery, a battery monitoring device, a mobile computing device, a laptop computer, a tablet computer, a games console, a remote control device, a home automation controller or a domestic appliance, a toy, a robot, an audio player, a video player, or a mobile telephone, and a smartphone.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general-purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote control device, a home automation controller or a domestic appliance including a domestic temperature or lighting control system, a toy, a machine such as a robot, an audio player, a video player, or a mobile telephone for example a smartphone.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. Circuitry for processing an analyte signal obtained from an electrochemical cell comprising a first electrode and a second electrode, the circuitry comprising:
a first converter, comprising a first input coupled to the first electrode and a first output, the first converter configured to:
establish a substantially constant first bias voltage at the first input; and
convert a first current at the first input to a first converted signal at the first output;
a second converter, comprising a second input coupled to the second electrode and a second output, the second converter configured to:
convert a second current at the second input to a second converter signal at the second output; and
processing circuitry configured to detect a fault in the circuitry based on the first and second converter signals.

2. Circuitry of claim 1, wherein the first converter comprises a transimpedance amplifier or a current conveyor.

3. Circuitry of claim 1, wherein the first converter is configured to mirror a voltage at a second input of the first converter at the first input of the first converter to establish the first bias voltage at the first input.

4. Circuitry of claim 1, wherein the second converter comprises a transimpedance amplifier or a current conveyor.

5. Circuitry of claim 1, wherein the processing circuitry comprises:
one or more analog-to-digital converters, ADCs, configured to convert the first converted signal to a first digital signal, and to convert the second converted signal to a second digital signal, the processing circuitry configured to detect the fault based on the first and second digital signals.

6. Circuitry of claim 5, wherein the processing circuitry comprises:
summing circuitry configured to sum the first and second digital signals to obtain a summed output signal; and
comparison circuitry configured to:
compare the summed output signal to a threshold output value; and
detect the fault in the circuitry based on the comparison.

7. Circuitry of claim 6, wherein the comparison circuitry comprises a hysteretic comparator.

8. Circuitry of claim 6, wherein the processing circuitry further comprises:
a low-pass filter coupled between the summing circuitry and the comparison circuitry.

9. Circuitry of claim 1, wherein the processing circuitry is configured to:
transmit a fault interrupt to a host device on detection of the fault.

10. Circuitry of claim 1, wherein the processing circuitry is configured to:
transition the circuitry into an error state on detection of the fault.

11. Circuitry of claim 1, wherein the processing circuitry is configured to:
power down the circuitry on detection of the fault.

12. Circuitry of claim 1, wherein the processing circuitry is configured to determine a characteristic of the electrochemical cell based on one or both of the first and second outputs.

13. Circuitry of claim 12, wherein the processing circuitry is configured to:
determine a mean of the first and second outputs; and
determine the characteristic of the electrochemical cell based on the mean.

14. Circuitry of claim 12, wherein the characteristic comprises one or more of:
an impedance;
an analyte concentration;
a state of health of the electrochemical cell.

15. Circuitry of claim 1, wherein the electrochemical cell comprises a third electrode, the circuitry further comprising:
a third converter, comprising a third input coupled to the third electrode and a third output, the third converter configured to:
convert a third current at the third input to a third converter signal at the third output.

16. Circuitry of claim 15, wherein the processing circuitry is configured to:
determine a characteristic of the electrochemical cell based on the third converter signal.

17. Circuitry of claim 15, wherein the first electrode is a counter electrode, and wherein the second and third electrodes are working electrodes.

18. Circuitry of claim 17, wherein the second and third electrodes are configured to detect different analytes in the electrochemical cell.

19. Circuitry of claim 1, wherein the electrochemical cell comprises a potentiostatic cell.

20. Circuitry of claim 1, wherein the electrochemical cell comprises a battery cell.

21. Circuitry for processing an analyte signal obtained from an electrochemical cell comprising a first electrode, a second electrode, and a third electrode, the circuitry comprising:
a first converter, comprising a first input coupled to the first electrode; a second input coupled to the second electrode; and a first output, the first converter configured to:
establish a substantially constant first bias voltage at the second input; and
convert a first current at the first input to a first converted signal at the first output;
a second converter, comprising a third input coupled to the third electrode and a second output, the second converter configured to:
convert a second current at the third input to a second converter signal at the second output; and
processing circuitry configured to detect a fault in the circuitry based on the first and second converter signals.

22. Circuitry of claim 21, wherein the first electrode comprises a counter electrode, the second electrode comprises a reference electrode, and the third electrode comprises a working electrode.

23. Circuitry of claim 22, wherein the second converter is configured to establish a substantially constant second bias voltage at the third electrode.

24. An integrated circuit (IC), comprising the circuitry of claim 1.

25. A wearable device, comprising:
circuitry of claim 1; and
the first and second electrodes.

26. The wearable device of claim 25, wherein the wearable device comprises one of an analyte monitor, a glucose monitor, a battery monitor, a mobile computing device, a smart watch, a remote control device, a home automation controller, an audio player, a video player, a mobile telephone, and a smartphone.
